(19) United States
(12) Patent Application Publication
(10) Pub. No.: US 2010/0258724 A1
(43) Pub. Date: Oct. 14, 2010

(54) Tip-sharpened carbon nanotubes and electron source using thereof

(75) Inventors: Mitsuo Hayashibara, Hitachinaka (JP); Tadashi Fujieda, Mito (JP); Kishio Hidaka, Hitachiota (JP)

Correspondence Address: MCDERMOTT WILL & EMERY LLP, 600 13TH STREET, N.W., WASHINGTON, DC, 20005-3096, US

(73) Assignee: HITACHI HIGH-TECHNOLOGIES CORPORATION

(21) Appl. No.: 11/645,601

(22) Filed: Dec. 27, 2006

(30) Foreign Application Priority Data
Dec. 28, 2005 (JP) 2005-376860
Mar. 6, 2006 (JP) 2006-058828

(51) Int. Cl. H01J 37/26; H01J 1/14; H01J 37/30; D01F 9/12; C01B 31/36; C01C 3/00

(52) U.S. Cl. 250/311; 313/346 R; 250/492.3; 423/447.8; 423/291; 423/384; 977/939; 977/743; 977/900; 977/842

(57) ABSTRACT

An electron microscope comprising an electron emitting cathode equipped with a carbon nanotube and an extraction unit to field-emit electrons. The carbon nanotube contains a sharp portion which is approximately conical shape at tip thereof closed at the electron-emitting cathode.

A method of manufacturing carbon nanotube having a sharp angle part at the tip thereof, comprising a step of placing and heat-treating a tip-sharpened carbon nanotube still at a lower temperature than a phase transition temperature and a step of placing and heat-treating a tip-sharpened carbon nanotube still at a higher temperature than a phase transition temperature.

### CLAIM OF PRIORITY

The present application claims priority from Japanese application serial No. 2005-376860, filed on Dec. 28, 2005 and Japanese application serial No. 2006-058828, filed on Mar. 6, 2006; the contents of which are hereby incorporated by references into this application.

### BACKGROUND OF THE INVENTION

1. Field of the Invention

This invention relates to carbon nanotubes whose tips are sharpened and application of the carbon nanotubes to electron sources.

2. Prior Art

Japanese Patent Application Laid-open publication No. 2004-079223 (Patent Document 1) has disclosed an electron source that can generate electron beams of high-intensity and narrow electron energy width. Various discussions have been made on electron sources but the relationship between beam patterns and electron-emission sites of carbon nanotubes have not been known. Particularly, it is said that dimensions of carbon nanotubes are quantized radially. From the point of view of the uncertainty principle, the size of said electron emission site has been greatly discussed by academic conferences. This makes electronic optical designing of electron guns difficult when characteristics of electron beams are used as electron sources for electron microscopes.

(Patent Document 1) Japanese Patent Application Laid-open publication No. 2004-079223

### SUMMARY OF THE INVENTION

To make observed microscopic images clear, the field intensity of the electron source of an electron microscope must be increased but there is a limit to voltage increase. Therefore, an object of this invention is to provide an electron source whose field intensity is improved without a voltage rise.

This invention to accomplish the above object relates to an electron microscope which comprises an electron emitting cathode equipped with a carbon nanotube and an extraction unit to field-emitting electrons and is characterized by using a carbon nanotube whose tip is approximately conical and sharp. Further, this invention is characterized by using a method which comprises a process of heat-treating the tip-sharpened carbon nanotube at a lower temperature and a higher temperature than the phase transition temperature.

This invention to accomplish the above object is characterized by a carbon nanotube electron source which provides a sharp part at the tip of the carbon nanotube. The sharp part is approximately conical, for example, like a sharpened end of a pencil. The above structure can improve the field intensity of the electron gun even when the applied voltage is constant.

The cone angle of the sharp part like a sharpened pencil end is preferably up to 120°. The field intensity of the electron source is expressed by E (Field intensity)=V (Applied voltage)/R (Curvature radius of the electron source tip). When the cone angle is about 120°, the curvature radius of the electron source tip is about ½. Consequentially, the resulting field intensity is doubled.

Here, the cone angle is the angle of a triangle which is formed when the sharpened tip of the carbon nanotube is projected onto a plane.

Furthermore, this invention to accomplish the above object is characterized by a method of manufacturing carbon nanotubes which comprises the steps of placing carbon nanotubes still and heat-treating the carbon nanotubes at a temperature ranging from 550° C. to 620° C. which is lower than the phase transition temperature (660° C. at which carbon nanotubes become amorphous) and at a temperature ranging from 700° C. to 1200° C. which is higher than the phase transition temperature at least once.

The durations of the above heat treatments should preferably be 0.8 to 4 hours at a lower temperature and 0.8 to 2 hours at a higher temperature.

Further, the electron source has a carbon nanotube jointed to a conductive base. Furthermore, this invention makes said carbon nanotube contain 0.1 to 5 atomic percent of at least one of boron, nitrogen, phosphor, and sulfur and sets the IG/ID ratio (where IG is a Raman scattering intensity due to expansion and contraction of carbon atoms in graphite structure and ID is a Raman scattering intensity due to crystal lattice disturbance) of the Raman spectroscopic intensity of the carbon nanotube to 0.75 or more. Particularly the tip of the carbon nanotube should preferably have a closed structure. The present inventors found that the electron energy width becomes smaller as the IG/ID ratio becomes greater (as the ratio of the graphite structure becomes greater). In other words, the inventors found that the crystallinity greatly affects the energy width and increases the ratio of the graphite structure in the carbon nanotube which contains non-carbon elements particularly boron, nitrogen, phosphor, and/or sulfur atoms and that, as the result, the energy width of the electron beam is reduced.

In accordance with the above structure, this invention can provide a carbon-nanotube electron source which generates electron beams of smaller energy width with a high current stability. Further, a high-resolution electron microscope and a high-definition electron-beam lithography system can be provided by using the above electron sources.

In accordance with the electron source of this invention, microscopic pictures of the electron microscope can be clear and distinct. Further, microscopic pictures of the similar levels can be obtained at a lower supply voltage and the durability of the electron microscope can be increased. Furthermore, the above electron source is preferable not only for electron microscopes but also for electron beam lithography system.

### BRIEF DESCRIPTION OF THE DRAWINGS

FIG. 1 is a system configuration of a Chemical Vapor Deposition (CVD) apparatus for manufacturing carbon nanotubes as an embodiment of this invention.

FIG. 2a is a drawing to show the tip of a conventional carbon nanotube before heat treatment.

FIG. 2b is a drawing to show the tip of a carbon nanotube of this invention after heat treatment.

FIG. 3 is a drawing to explain a heat treating process of the other embodiment of the invention.

FIG. 4 is a drawing to show how the length of carbon nanotube is affected by a heat treatment process.

FIG. 5 is a schematic diagram of a carbon nanotube electron source for an electron microscope in accordance with this invention as another embodiment of this invention.

FIG. 6 is a drawing to show a carbon nanotube whose tip vertex is not on the axis of rotation.

FIG. 7 is a drawing to show the Raman scattering spectra of materials in accordance with this invention.

FIG. 8 is a drawing to show a basic configuration of an electron source in accordance with this invention.

FIG. 9 is a drawing to show the result of measurement of energy widths of an electron source in accordance with this invention.

FIG. 10 is a drawing to show the result of measurement of current stability of an electron source in accordance with this invention.

FIG. 11 is a drawing to show the result of measurement of energy widths of an electron source in accordance with this invention.

FIG. 12 is a drawing to show the result of measurement of energy distribution of an electron source in accordance with this invention.

FIG. 13 is a drawing to show the result of measurement of energy distribution of an electron source in accordance with this invention.

FIG. 14 is a drawing to show the result of measurement of energy distributions of an electron source in accordance with this invention and an electron source which is a comparative example.

FIG. 15 is a drawing to show the configuration of a scanning electron microscope which uses an electron source in accordance with this invention as other embodiment of the invention.

FIG. 16 is a drawing to show the whole configuration of an electron beam lithography system equipped with an electron source of this invention as other embodiment of the invention.

### DETAILED DESCRIPTION OF THE INVENTION

Below will be explained details of the embodiments of this invention.

### Embodiment 1

### Method of Manufacturing Carbon Nanotubes

Representative methods of manufacturing carbon nanotubes are Arc-Discharging, Laser Abrasion, and Chemical Vapor Deposition (CVD) methods.

In the Arc-Discharging method, two graphite rods of 10 mm in diameter and 100 mm long with their ends are faced to each other and with their center axes matched with each other. First, the rods were pulled together until their opposing end surfaces touch each other, and then separated from each other to make a space of about 1 to 2 mm between their opposing end surfaces. It is possible to apply a d.c. voltage to these graphite rods to arc-discharge, but resulting carbon nanotubes may be contaminated by gas components in the atmosphere.

To prevent this, the test chamber equipped with the two graphite rods was vacuumed by a rotary vacuum pump to remove gas components.

Inactive gas such as helium (He) or argon (Ar) was supplied to the test chamber and controlled the chamber pressure approximately to the atmospheric pressure. Arc-discharging was made by applying current of 150 to 200 A at a voltage of 10 to 20 V to the graphite rods. Arcs flying from the cathode graphite rod to the anode graphite rod evaporated graphite from the end surface of the anode graphite rod and deposited carbon nanotubes on the end surface of the cathode graphite rod.

To deposit carbon nanotubes continuously on the end surface of the cathode graphite rod, the space between the end surfaces of the graphite rods was controlled to be constant by feeding the graphite rods.

The above gap was continuously controlled while arc-discharging with the above current at the above voltage.

When arcs attack a single point on the end surface of a graphite rod, the carbon nanotube is deposited horn-like on the surface. This horn-like deposition may short-circuit the cathode and anode graphite rods and cause a current leak.

It is possible to produce boron-doped carbon nanotubes by preparing graphite rods, boring a center hole in the graphite rod, filling the hole with metallic boron or carbon boride, and arc-discharging under the similar arc-discharging conditions. In this case, the arc-discharging conditions are the same. The content of boron in the carbon nanotube can be controlled by the quantity of boron in the hole and should preferably be 0.5 to 5 mol % judging from the hardness of the carbon nanotube and the electron emission characteristics of the carbon nanotube used in an electron microscope.

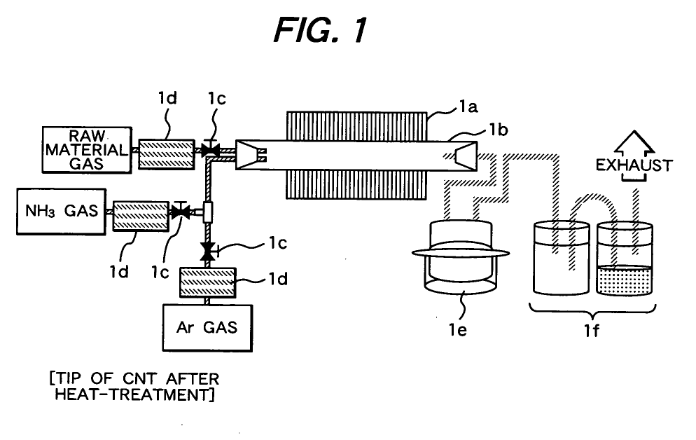

Next will be explained a production of carbon nanotubes by the Chemical Vapor Deposition (CVD) method. A thermal CVD method was used to produce carbon nanotubes. FIG. 1 shows a system configuration for the thermal CVD method as an embodiment of this invention. A liquid organic solvent such as toluene or methanol is used as a raw material of carbon nanotubes. First, the organic solvent was evaporated. There are two methods to evaporate the solvent: a method of feeding organic solvent into a reactor tube 1b by a syringe and evaporating the solvent in the reactor tube 1b and a method of evaporating the solvent in advance and feeding the solvent vapor into the reactor tube 1b through a flow meter 1d or valve 1c to control the flow rate. Argon gas (Ar) was used as a carrier gas to dilute the solvent vapor. The solvent vapor is reacted into carbon nanotubes on a substrate or in a vacuum reactor tube 1b by using catalyst. The catalyst can be selected from a group of iron acetate, ferrocene, nickel acetate, nickelocene, and cobalt acetate. To grow carbon nanotubes on a substrate, a silicone substrate is coated with a liquid of one or more catalysts. To grow carbon nanotube in a gas phase in the reactor tube 1b, catalysts are dissolved into the organic solvent of the raw material and evaporated together with the solvent.

The inventors produced carbon nanotubes were produced in the furnace 1a at a furnace temperature of 600 to 1200° C. Carbon nanotubes were produced and deposited on a substrate (in the substrate method) or on the inner wall of a vacuum reactor tube 1b (in the gas-phase method). Further, carbon nanotubes produced in the gas phase were exhausted together with the gas, trapped and recovered in the succeeding steps.

When a nitrogen-containing carbon compound such as melamine or pyrazine was added to the liquid organic solvent, nitrogen-doped carbon nanotubes were produced. In this case, a mixture of argon and ammonia gases was used as the carrier gas. The content of nitrogen in carbon nanotube could be controlled in the range of 1 to 5 atomic % by keeping the ratio of argon (Ar) to ammonia in the range of 1:1 to 20:1. The content of nitrogen in carbon nanotube could be controlled in the range of 2 to 4 atomic % by keeping the ratio of argon (Ar) to ammonia at about 10:1. The content of nitrogen in carbon nanotube increased as the ratio of ammonia gas became greater. The temperature of the reactor tube 1b should preferably be 800 to 1000° C. The nitrogen content increased as the temperature went lower.

The gas flow rate must be changed in accordance with the diameter of the reactor tube 1b. The total gas flow rate per unit area should preferably be 1.0 to 100 ml/cm²/min. This embodiment flowed gas at a rate of 20 ml/min through a quartz tube of 60 mm in internal diameter.

(Method of Manufacturing Sharpened Carbon Nanotubes)

Below will be explained a method of manufacturing carbon nanotubes each of which has a sharp part at the tip.

The carbon nanotubes for heat-treatment of this invention were prepared by the above manufacturing methods. Prepared carbon nanotubes were carbon nanotube (A) that contains only carbon atoms, carbon nanotube (B) that contains boron atoms in addition to carbon atoms, and carbon nanotube (C) that contains nitrogen atoms in addition to carbon atoms. Carbon nanotubes (A) and (B) were prepared by the Arc-Discharging method but carbon nanotube (C) was prepared by the CVD method. Each of these prepared carbon nanotubes had an approximately hemispheric tip. The above carbon nanotubes were placed still in a vacuum heat-treatment apparatus and heat-treated in a vacuum atmosphere of 1×10⁻³ Pa or lower. The heat treatment can be conducted in an inactive gas such as argon, helium, or nitrogen gas or in the atmospheric pressure.

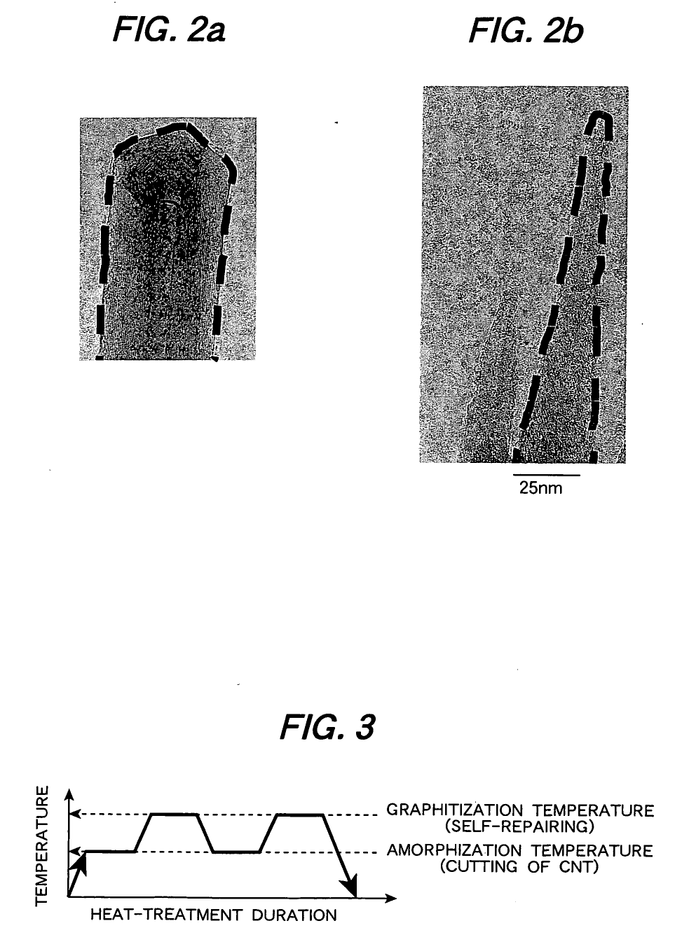

The low-temperature heat treatment was conducted at 600° C. for one hour, increased the apparatus temperature to 1050° C. (for high-temperature heat treatment) at a rate of 10° C./minute, kept the temperature for one hour, and then cooled the apparatus. The resulting carbon nanotube is about 25 nm thick and has a cone angle of about 10° while the prepared carbon nanotube before heat-treatment is about 25 nm thick and has a cone angle of about 130°. FIG. 2 shows the difference between carbon nanotubes before the heat-treatment in FIG. 2 a and carbon nanotubes after the heat-treatment in FIG. 2 b.

When the temperature is increased in a vacuum atmosphere higher than 1×10⁻³ Pa, carbon nanotubes can be amorphous at a temperature of about 660° C. (phase transition temperature) or lower. At a temperature higher than the phase transition temperature, the half-amorphous carbon material is turned into graphite. By placing carbon nanotubes still during the heat-treatment, carbon nanotubes whose tip shape is different from that before the heat-treatment could be obtained.

The temperature for the low-temperature heat-treatment should preferably be 550 to 620° C. This is because the amorphization does not advance so quickly under 550° C. Further, at a temperature over 620° C. which is too close to the phase transition temperature, carbon nanotubes are made amorphous and graphite simultaneously.

The temperature for the high-temperature heat-treatment should preferably be 700 to 1200° C. This is because a phase transition from graphite to carbon nanotube does not advance under 700° C. Further, at a temperature over 1200° C., a phase transition from carbon nanotube to graphite may occur. Particularly, at a temperature over 2000° C. (graphite transition temperature), the cylindrical structure of carbon nanotube may be broken into individual planar graphite sheets.

The durations of the above heat treatments should preferably be 0.1 to 8 hours at a lower temperature and 0.1 to 2 hours at a higher temperature. If the duration is 0.1 hour or shorter, carbon nanotubes cannot be fully amorphous. Contrarily, if the duration is 4 hour or longer, carbon nanotubes are made amorphous too much and their shapes may be broken. If the duration is 0.1 hour or shorter in the high-temperature heat treatment, the phase transition into graphite is insufficient. Heat treatment of 2 hours or longer will not cause carbon nanotubes to change.

When the above heat treatment was conducted during stirring, carbon nanotubes were cut but their tips were not sharpened.

The phase transition is for the first-order transition and a phase transformation. Since the phase transition is a thermal activation process, the reaction cannot proceed quickly without enough heat supply. This is quite a contrast to the second-order transition such as a magnetic transformation temperature at which the reaction proceeds with one push when the transition temperature reaches. It is generally known that the activation energy follows the Arrenius theory in which the activation energy increases exponentially. In addition, it is assumed that a transformation can start at a comparatively low temperature in a warped part which contains atomic fractures such as vacancies, sets of fractures, and five-membered carbon rings.

The transformation requires energy to make geometrical atomic rearrangement. The energy required for rearrangement can be less when the structure contains fractures but greater when the structure contains no fracture. Therefore, the phase transition temperature of carbon nanotube is comparatively wide (660±40° C.). When the heat-treatment temperature is set within this range, reactions on carbon nanotubes may not be uniform. Therefore, such a temperature range must be avoided.

### Embodiment 2

As shown in FIG. 3, the above heat-treatment processes were repeated twice. The heat-treatment temperature and duration of this embodiment are the same as those of Embodiment 1. The resulting carbon nanotube is sharpened more at the tip. However, because of multiple heat-treatments, part of carbon nanotube was cut and the resulting carbon nanotubes were short as the whole.

Amorphization of carbon nanotubes starts first from the above fractured parts. If carbon nanotube contains fractures, fracture may start from that part. When heat-treatment is repeated twice, two or three parts of a carbon nanotube (e.g. 10 μm long) are made amorphous and consequently the carbon nanotube may be cut into shorter pieces.

### Embodiment 3

Next, influences of the heat treatment on the length of carbon nanotube was examined. The duration of the low-temperature heat treatment in Embodiment 2 was changed, the heat treatment was repeated twice, and the length of the resulting carbon nanotube was measured. The inventors measured lengths of 500 carbon nanotubes for each specimen, rounded up the lengths to integers, and grouped them at intervals of 1 μm (1, 2, 3, 4, 5, 6, 7, 8, 9 and over 10).

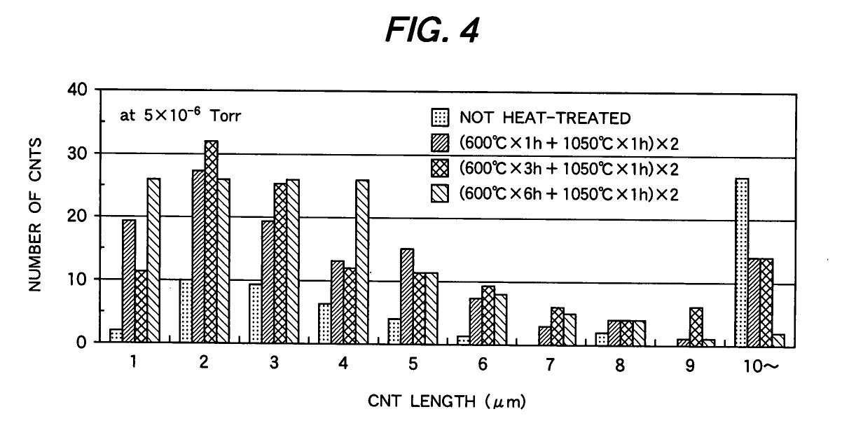

FIG. 4 shows the result of measurement. Before the heat treatment, most of the carbon nanotubes were 10 μm or longer. After the heat treatment, however, shorter carbon nanotubes (than 10 μm) increased in number. When the heat treatment was conducted at 600° C. for 3 hours, carbon nanotubes of 2 μm were more than those obtained by heat treatment of 1 hour. When the heat treatment was conducted at 600° C. for 6 hours, carbon nanotubes of 1 to 4 μm were as many as those obtained by heat treatment of 1 hour.

Accordingly, the heat treatment time for amorphization should preferably be shorter if long carbon nanotubes are required. Substantially, the duration should be 0.5 hour or shorter. Further, the heat treatment time should be 5 hours or longer to prepare carbon nanotubes of different lengths.

### Embodiment 4

### Electron Source Using Tip-Sharpened Carbon Nanotubes

An electron source was created by using carbon nanotubes created in the embodiment 1. The carbon nanotubes are made of carbon atoms and respective carbon nanotubes is about 25 nm in diameter, about 5 μm in length, and about 10° in cone angle.

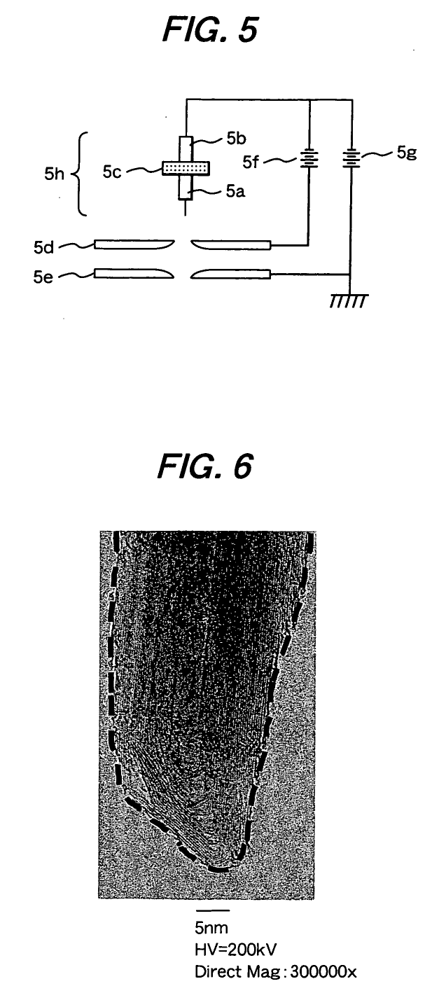

FIG. 5 shows the schematic diagram of a carbon nanotube electron source for an electron microscope in accordance with this invention. The electron source of FIG. 5 comprises, for example, a single carbon nanotube 5a whose tip has a sharp part, a cathode 5h made of a conductive base 5c for supporting the carbon nanotube 5a, an extraction unit 5d for field-emitting electrons, and an accelerator 5e for accelerating electrons.

The operations of an electron source that contains a single carbon nanotube whose tip has a sharp part was tested. As a reference example, a similar electron source that uses an ordinary carbon nanotube whose tip is round was prepared and tested its operation similarly.

In some cases, the vertex of the tip of the carbon nanotube 5a before a heat treatment is not in the rotational center (axis) of the carbon nanotube (see FIG. 6). However, the vertex of the sharpened tip of the carbon nanotube after a heat treatment is placed on the extension of the axis (the center of the carbon nanotube). As the result, the electron source using the tip-sharpened carbon nanotube of this invention has the beam position fixed and facilitates adjustment of the beam axis. Furthermore, this electron source is characterized by straight beam emission and low noise.

The tip-sharpened carbon nanotube can increase the current density in proportion to the voltage. For example, the carbon nanotube of this invention can field-emit electrons at a voltage of 0.5 kV although the ordinary carbon nanotube requires 2 kV (the threshold voltage) to field-emit electrons. As the result, this invention can provide an electron source or electron microscope of low power consumption with less power load. Further, the carbon nanotube can increase the current density and the field intensity at the same voltage. This can make microscopic images brighter. Therefore, this invention can provide a high-definition electron microscope.

Adoption of a field superimposition has been discussed as a means for converging electron beams and increasing the resolution of an electron microscope. This method collects electron beams to utilize beam current unlike scattering of electron beams by a conventional electromagnetic field lens. When adopted, the electron source of this invention facilitates field superimposition since the diameter of the tip of the electron source is very small. This is one of effects of this invention.

### Embodiment 5

Next, this invention provides an electron source which uses a carbon nanotube whose crystallinity is increased by addition of a preset quantity of boron, nitrogen, phosphor, or sulfur to the carbon nanotube so that the carbon nanotube may have more graphite structure.

For reduction of electron energy width and improvement of current stability, it is preferable to use a solid or hollow carbon nanotube whose tip is approximately axis-symmetrical (where the tip of the carbon nanotube is symmetric relative to the center axis of the carbon nanotube as in a conical shape).

For reduction of an electron energy width, it is preferable that impurity atoms such as boron, nitrogen, phosphor, and sulfur in the carbon nanotube structure are substituted by carbon atoms. Particularly, the energy width can be reduced most when any of boron, nitrogen, phosphor, and sulfur atoms has a pyridine structure or when impurity atoms of the same kind exist closest to the impurity atoms.

For reduction of an electron energy width, it is preferable that the energy width of electrons that are emitted into a vacuum space from a single carbon nanotube is 0.25 eV or less when the current density is 0.01 to 0.1 μA. Particularly, when the current is 0.01 to 0.1 μA, the energy width will hardly be affected by the other factors (e.g., space charge effect) and the energy width is that of the raw material itself. Therefore, this invention can use excellent material characteristics.

The above structure is preferable since the half value width in the high energy side can be within 0.15 eV relative to a reference point (the maximum peak point in the electron energy distribution) and the half value width in the low energy side can be within 0.3 eV relative to the reference point at a current of 0.1 to 1.0 μA. The above result can be obtained when electrons are field-emitted and no thermal electron of a greater energy width is emitted.

It is preferable that a current change is 0.2 eV or less at a rise position (half value width) of the high energy side in the electron energy distribution when the current is 0.1 to 1.0 μA. When the resistance of the electron source is great, the electron source becomes hot and emits thermal electrons. However, since the resistance of the electron source is small, emission of thermal electrons can be suppressed. Particularly, it is preferable that the tip of the carbon nanotube is approximately hemispheric or locally flat (like a cup).

As for the above carbon nanotube, the diameter of a single carbon nanotube or carbon nanotubes in a bundle should preferably be 50 nm to 200 nm. This diameter range can suppress the Boerch effect which increases the energy width by concentration of electron density. Further, this diameter range can reduce the resistance of the carbon nanotube and consequently reduce emission of thermal electrons by heat generation of the carbon nanotube. Any of the above effects can reduce the energy width.

It is preferable to use carbon nanotubes of 2 to 10 μm long and let the carbon nanotubes project 0.5 to 3.0 μm from the conductive base. Particularly, when bonding a carbon nanotube(s) to the conductive base, it is preferable to apply a metal-contained bonding layer of 50 nm or thicker and coat an area of 0.5 μm or more of the carbon nanotube. Further, it is preferable to reduce the total resistance of the conductive base and the carbon nanotubes under 20 kΩ. This can reduce emission of thermal electrons caused by heat generated by the carbon nanotube (CNT) that is emitting electrons, so that the energy width can be reduced.

Below is explained a method of preparing carbon nanotubes used in the above embodiments.

(1) Method of Preparing Boron-Doped Carbon Nanotubes.

Boron-doped carbon nanotubes were prepared by applying B₄C powder to the surface of the graphite plate, connecting the anode (+) to the graphite plate and the cathode (−) to the tungsten electrode of the TIG welding torch, arc-discharging with a current of 200 A for one second while flowing argon gas into the reaction furnace.

(2) Method of Preparing Carbon Nanotubes Doped with Boron, Phosphor, and Sulfur.

Carbon nanotubes doped with boron, phosphor, and sulfur were prepared by placing a graphite target which contains boron, phosphor, and sulfur in argon gas (at 500 Torr), heating the target at about 1100° C., applying Nd:YAG laser (1064 nm, 10 Hz) to the target, and melting and evaporating the target.

(3) Method of Preparing Nitrogen-Doped Carbon Nanotubes. (1)

Nitrogen-doped carbon nanotubes were prepared by the following process.

Dissolving aluminum tri-sec-butoxy (8 grams) in methanol (50 ml), stirring the solution until it became clear, adding HCl (0.01 mM) to the solution, adding ferrous sulfate Fe(NO₃)₃.9H₂O (3.2 grams) thereto, adding ammonia solution to gelate the solution, drying the solution at 100° C., baking thereof at 600° C. for 10 hours, and resulting the supporting catalyst was made. Next, putting the supporting catalyst in a tube-like quartz electric furnace, heating the furnace to 800° C. while flowing argon gas (200 sccm) through the furnace, and supplying hydrogen gas (100 sccm) into the furnace for 1 hour to reduce the oxide in the supporting catalyst. Then, feeding dimethyl formamide HOCN(CH₃)₂ together with argon gas (as the carrier gas) into the furnace (quartz tube), and feeding absolute ammonia gas (100 sccm) into the furnace at the same time.

(4) Method of Preparing Nitrogen-Doped Carbon Nanotubes. (2)

Nitrogen-doped carbon nanotubes were prepared by putting a mixture of 4 parts of melamine powder (s-triaminotriazine) and 1 part of ferrocene powder (dicyclopentadieny-liron) in the tubular quartz electric furnace, and heating the powder mixture at 1050° C. for 15 minutes while flowing argon gas (0.8 liter/min) through the furnace.

(5) Method of Preparing High-Crystallinity Carbon Nanotubes.

High-crystallinity carbon nanotubes were prepared by heating carbon nanotubes that were prepared by the above methods (1) to (4) for about 30 minutes at 1000 to 2100° C. in a vacuum state. The above heat treatment can be carried out in an inactive gas atmosphere (e.g., argon, helium, or nitrogen gas) at an atmospheric pressure.

Another heat treatment was conducted also at 1500° C. The IG/ID value of the resulting carbon nanotube was between 1000 and 2100.

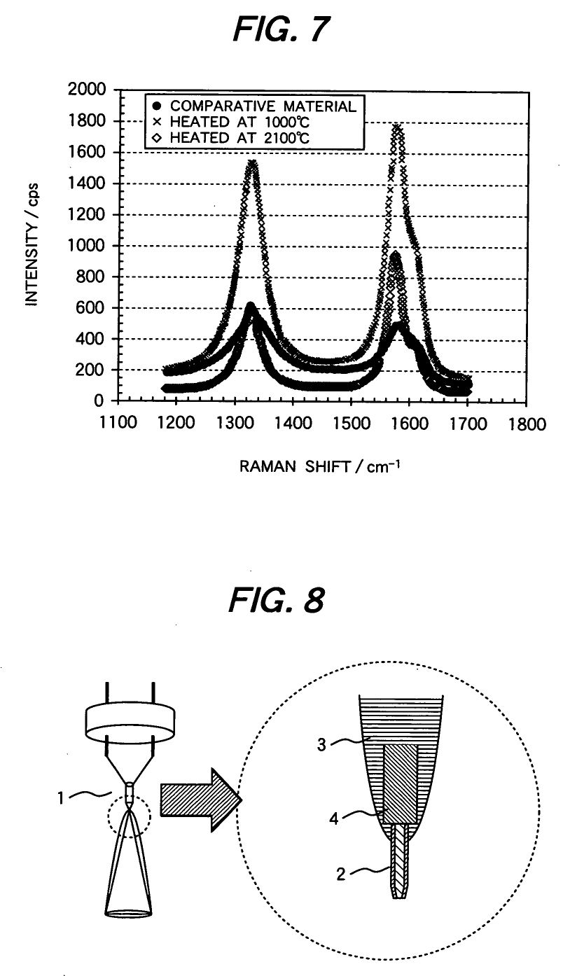

FIG. 7 shows the Raman scattering spectra of nitrogen-doped carbon nanotubes that were prepared by the above method (4) respectively before and after the heat treatment. Their IG/ID values were calculated from the ratio of areas at a peak of each spectrum. The IG/ID value of carbon nanotubes that were heat-treated at 1000° C. is 0.75 while the IG/ID value of carbon nanotubes (marked by a dot “•” in FIG. 7) that were prepared by a conventional method but not heat-treated is about 0.7.

### Embodiment 6

FIG. 8 shows a schematic configuration of an electron source that uses a carbon nanotube of this invention. Electron source 1 consists of one carbon nanotube 2 and conductive layer 4 that bonds the carbon nanotube to conductive base 3. Materials of the conductive base 3 are not limited but should preferably be noble metals (e.g., gold, silver, and platinum group), crystalline carbon or high melting-point metals (e.g., tungsten, tantalum, niobium, and molybdenum) judging from the viewpoint of melting points, oxidation resistance, and mechanical intensity. The carbon nanotube 2 was bonded to the conductive base 3 by applying an electron beam to at least one part of a bonded area to which the carbon nanotube is to be bonded in a chamber through which an organic gas that contains conductive elements is flowed, forming the conductive layer 4 there, and the bonding carbon nanotube 2 whose tip has a closed structure to the conductive base 3. The organic gas for the bonding process should preferably be pyrene monomer or tungsten carbonyl. By applying electron beams to these organic gases, a conductive material layer such as a carbon layer or tungsten layer can be formed locally only on the junction between the carbon nanotube and the conductive base.

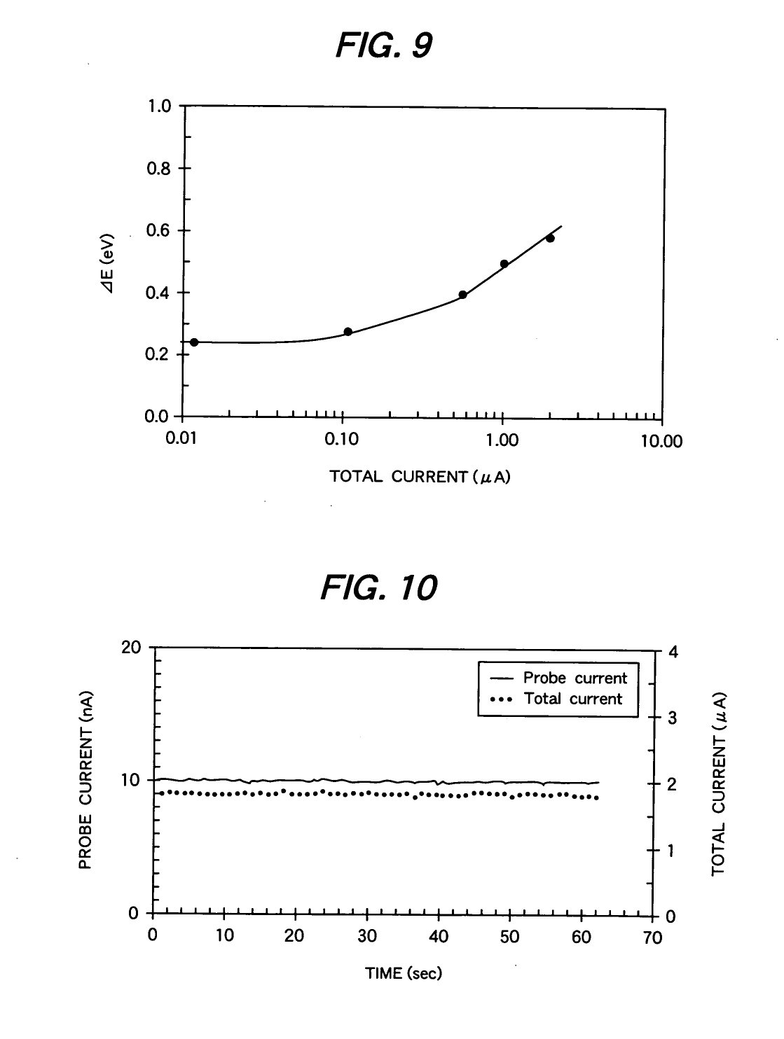

FIG. 9 shows the result of measurement of energy widths of an electron source equipped with a nitrogen-doped carbon nanotube (CNT) that was heat-treated at 1000° C. The IG/ID ratio of the CNT is 0.75. As seen from FIG. 9, the electron source using the carbon nanotube of this invention has an energy width of 0.25 to 0.5 eV at a current of 0.01 to 1.0 μA. This electron source is found to be superior to an electron source equipped with a carbon-only nanotube (0.5 to 0.7 eV). One of the reasons for this superior energy width can be explained by addition of boron, nitrogen, phosphor, or sulfur atoms. The added impurities improve the crystallinity of the carbon nanotube, narrow the energy band, and consequently make the energy levels sharp. For the other reason, since the crystallinity of the carbon nanotube is improved, the resistance of the carbon nanotube decreases and as the result, emission of thermal electrons that increase the energy width is suppressed. In FIG. 9, the energy width strikingly increases in the area of over 0.1 μA as the current increases. This is due to the Boerch effect. This problem can be dissolved by increasing the diameter of the carbon nanotube. Usually, the increment in the energy width due to the Boerch effect should preferably be 0.1 eV or less. However, if the diameter of the carbon nanotube is 100 nm, a satisfactory improvement can be accomplished.

FIG. 10 shows a current fluctuation stability (current variation width/mean current value) of carbon nanotubes. This test used a carbon nanotube whose tip is closed, axis-symmetric, and hemispheric. As seen from the test result, the current fluctuation stability of carbon nanotube of this invention is superior (2% or less). Contrarily, the current fluctuation stabilities of carbon nanotubes that are not heat-treated are about 5% or more.

When impurities such as boron, nitrogen, phosphor, and sulfur atoms are added to carbon nanotubes, the prepared carbon nanotubes contain more straight carbon nanotube. Therefore, carbon nanotube electron sources can be manufactured at high yields.

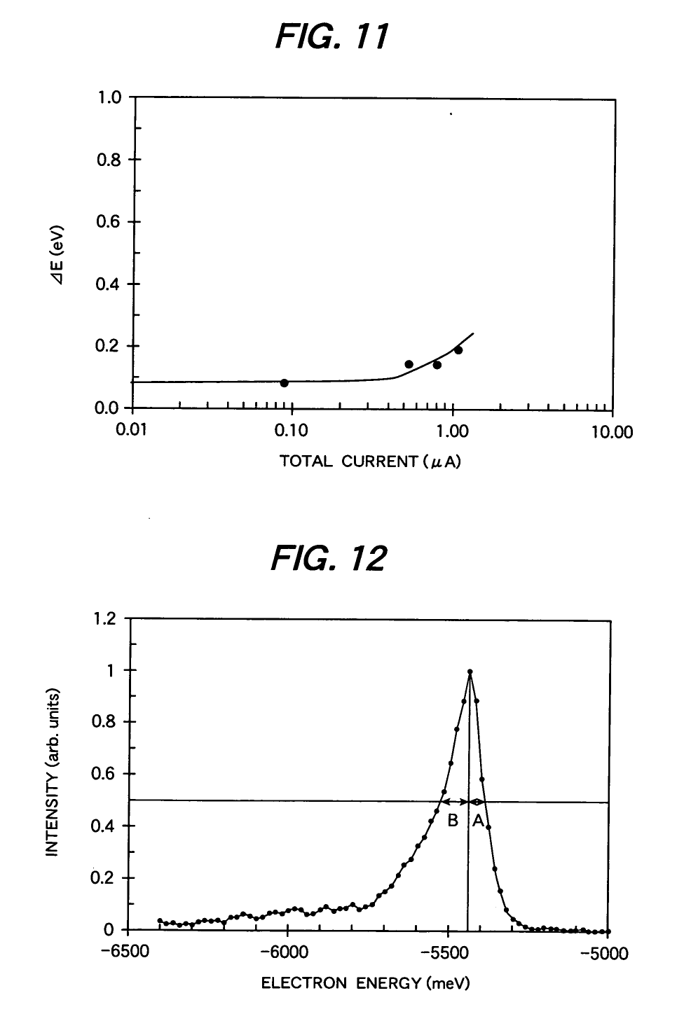

By analyzing carbon nanotubes contain 2 to 5 atomic % of these atomic elements that the carbon nanotube contains a pyridine structure in which a nitrogen atom is closest to another nitrogen atom. In comparison to a simple substitution structure in which a carbon atom is closest to a nitrogen atom, a carbon nanotube having a structure in which an impurity atom is closest to another impurity atom can show an excellent energy width (0.25 eV in the area of 0.01 to 1.0 μA in FIG. 11) when assembled into an electron source. It is assumed that this effect is due to a fact that a level of a narrow energy width due to impurity doping is formed near the Fermi level.

### Embodiment 7

Next will be explained another electron source which is prepared in accordance with this invention as another embodiment of the invention. It is found that the preferable diameter (φ) of the carbon nanotube for an electron source is 50 to 200 nm. If the diameter is smaller, the Boerch effect appears that is a phenomenon of increasing the energy width of electrons. This is because the current density becomes greater to obtain a required current. Contrarily, if the diameter of the carbon nanotube is increased, the carbon nanotube is apt to be curved. This embodiment uses a carbon nanotube which is about 60 nm in diameter and about 5 μm long. From the viewpoint of bonding to the conductive base, it is found that the preferable length of carbon nanotube is 3 to 10 μm. This is because longer carbon nanotubes are hard to be handled and shorter carbon nanotubes will increase the resistance in contact with the conductive base. It is also found that the projection of a carbon nanotube above the conductive base is optimally 0.5 to 3 μm long. A longer projection caused the projected carbon nanotube to vibrate. Further, it is found that a longer projection increases the resistance of the electron source and allows emission of thermal electrons (that increase energy widths). Contrarily, a shorter projection weakens the field intensity and consequently suppresses emission of electrons.

FIG. 12 shows the energy distribution of electrons that are emitted at a current of 0.1 μA from an electron source equipped with a nitrogen-doped carbon nanotube (containing 2% of nitrogen atoms as impurities) whose IG/ID ratio is 1.0 and which is projected about 1 μm from the base. When the maximum peak position in the electron energy distribution is used as a reference point, the half value width in the high energy side is within 0.15 eV relative to the reference point at a current of 0.1 to 1.0 μA and the half value width in the low energy side is within 0.3 eV relative to the reference point. The steep value rise in the high energy side is a characteristic of field electron emission. By this steep value rise, the inventors could confirm that a field-emission type electron source has been produced.

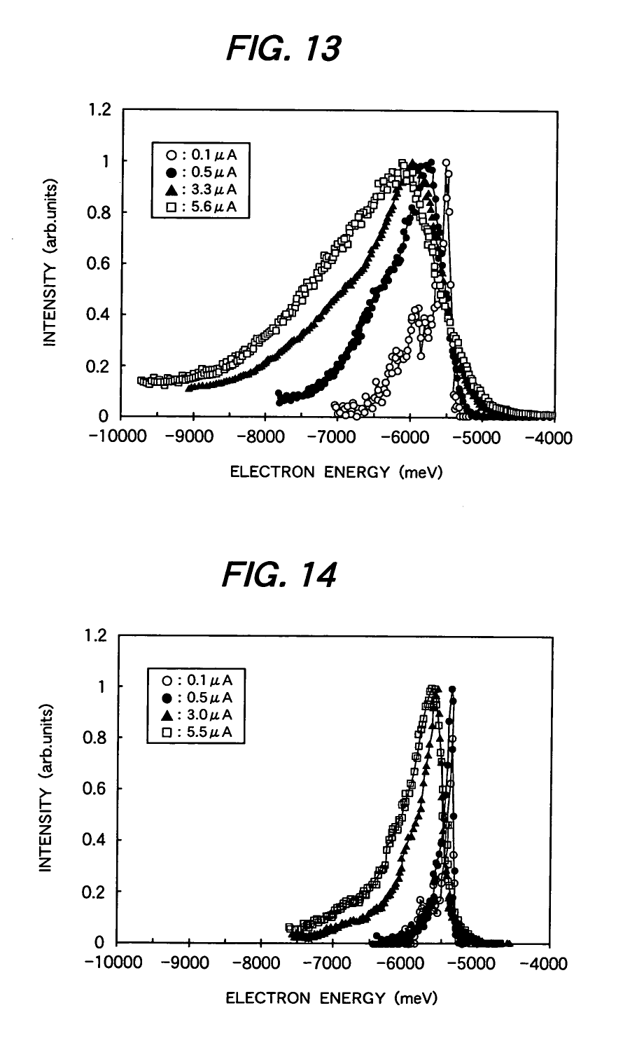

FIG. 13 shows the result of measurement of changes in energy distribution when the current applied to the prepared electron source was varied from 0.1 to 5.6 μA. In general, the energy width change should preferably be 0 and at most 0.1 eV or less. As seen from FIG. 13, however, the value rise in the high-energy side becomes dull as the current increases. At the same time, the energy width also increases strikingly. This is mainly because the carbon nanotube becomes hot by heat generated by current passing through the carbon nanotube (resistor) and emits thermal electrons.

FIG. 14 shows changes in energy distribution of an electron source whose carbon nanotube is bonded to the conductive base with a bonding conductive layer of 50 nm or thicker applied to 0.5 μm or more of the carbon nanotube. In this example, the rise position change is 0.2 eV or less and the increase of the energy width is suppressed. It is assumed that this improvement is made by reduction in the resistance of the junction (between the carbon nanotube and the base) and the total resistance of the electron source is reduced under 20 kΩ. FIG. 13 shows changes in energy distribution of an electron source whose carbon nanotube is bonded to the conductive base with a bonding conductive layer of 60 nm applied to about 0.7 μm of the carbon nanotube.

### Embodiment 8

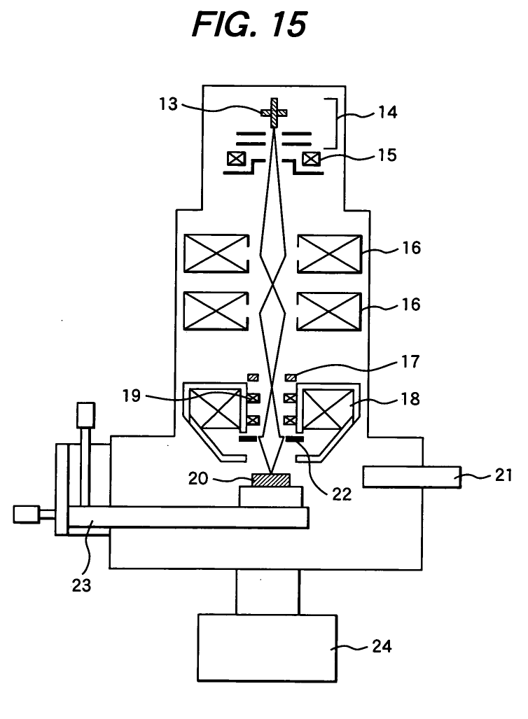

FIG. 15 shows the whole system configuration of a scanning electron microscope which uses an electron gun in accordance with this invention as other embodiment of the invention. The scanning electron microscope consists of an alignment coil 15, condenser lens 16, an astigmatic correction coil 17, a deflection/scanning coil 19, object lens 18, and an objective aperture 22 which are arranged along electron beams emitted from the electron gun 14. A test specimen 20 is placed on the specimen stage 23 and exposed to an electron beam. A secondary electron detector 21 is provided on the lateral wall of the specimen chamber which can be kept in a high vacuum status by an evacuation system 24. In this structure, an electron beam emitted from the electron gun 14 is accelerated by the anode, and converged by the electron lens to a micro test area of the specimen 20. The test area is two-dimensionally scanned. A secondary electron detector 21 detects secondary and reflected electrons from the specimen 20 and forms a magnified image of the specimen 20 according to differences of the detected signals.

It is possible to accomplish a scanning electron microscope (SEM) that is extremely superior in acquiring high-resolution and high-intensity secondary or reflected electronic images quickly to conventional electron microscopes by applying the electron gun of this invention to the scanning electron microscope. Further, the electronic optical system of a critical dimension scanning electron microscope for semiconductor processes to observe micro-fabrication patterns and to measure dimensions is basically the same as the configuration of FIG. 15 and can accomplish the same effect.

Naturally, the configuration of the scanning electron microscope equipped with a field emission type electron gun is not limited to the configuration of FIG. 15 and can be applied to any conventional well-known configuration as long as it can fully extract the characteristics of the field emission type electron gun.

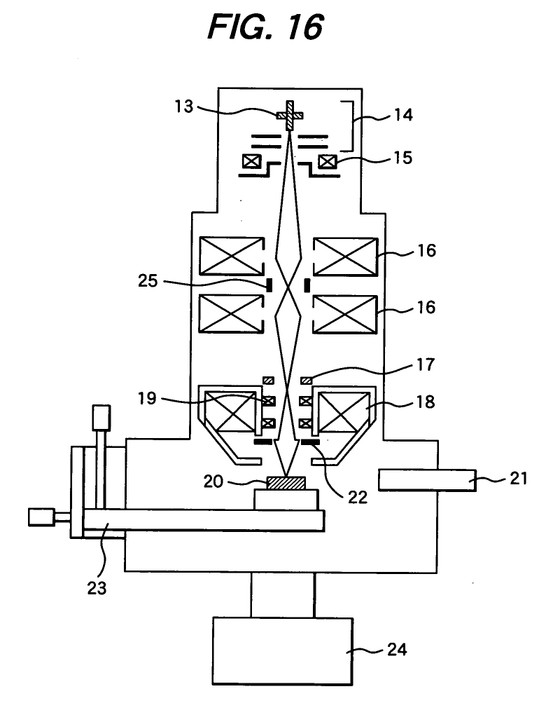

FIG. 16 shows an example of whole configuration of an electron beam lithography system equipped with an electron gun of this invention as other embodiment of the invention. The basic configuration of the electric optical system is approximately equal to that of the scanning electron microscope mentioned above. The electron beam lithography system field-emits an electron beam from the electron gun 14, converges the electron beam by the condenser lens 16, and converges the beam onto a specimen 20 by the objective lens 18 until a beam spot of a nanometer level. In this case, the center of the blanking electrode 25 (that controls the on/off state of electron beams) should preferably match with the cross-over point obtained by the condenser lens 16.

Electron beam lithography is carried out by deflecting and scanning an electron beam over a specimen 20 by the deflecting and scanning coil 19 while turning on and off the electron beam by the blanking electrode 25.

An electron beam lithography system applies electron beams to a specimen substrate which is coated with a photo-resist material that is sensitive to electron rays and forms circuit patterns on the substrate. However, as the circuit patterns have become smaller and more complicated, the electron guns have required smaller probe diameters. When adopted, the electron gun of this invention can provide an extremely bright and fine probe diameter (superior to conventional types) and enable high efficiency and high definition electron beam lithography.

The electron source of this invention and a carbon nanotube to accomplish thereof are available to electron microscopes, analyzers and processing equipment which use electron rays, and particularly to measuring system and processing system which are applicable to semiconductor technologies of next generation and generation after the next generation.

What is claimed is:

1. An electron microscope comprising an electron emitting cathode equipped with a carbon nanotube and an extraction unit to field-emitting electrons, wherein
the carbon nanotube contains approximately conical shape portion at the tip thereof closed at the electron-emitting cathode.

2. An electron microscope according to claim 1, wherein an angle of the approximate conical shape portion of the carbon nanotube is 120° or less.

3. An electron microscope according to claim 1, wherein a diameter of the carbon nanotube is 30 nm or less.

4. An electron microscope according to claim 1, wherein the carbon nanotube contains 0.5 to 5.0 mol % of boron or nitrogen.

5. An electron microscope according to claim 1, wherein a vertex of the approximate conical shape portion of the carbon nanotube is on the central axis of rotation of the carbon nanotube.

6. A method of manufacturing carbon nanotube having a sharp angle part at the tip thereof, comprising a step of placing and heat-treating carbon nanotube still in an atmosphere of a lower temperature ranging from 550 to 620° C. and then, a step of placing and heat-treating the carbon nanotube still in an atmosphere of a higher temperature ranging from 700 to 1200° C.

7. A method of manufacturing carbon nanotube according to claim 6, wherein the heat treatment step at the lower temperature is 0.1 to 8 hours long and the heat treatment step at the higher temperature is 0.1 to 2 hours long.

8. A method of manufacturing carbon nanotubes according to claim 6, wherein the heat-treatment steps at the lower temperature and the higher temperature are repeated.

9. A method of manufacturing carbon nanotubes according to claim 6, wherein the carbon nanotube to be heat-treated contains boron or nitrogen.

10. An electron microscope according to claim 1, wherein the carbon nanotube contains 0.1 to 5 mol % of at least one of boron, nitrogen, phosphor, and sulfur and the IG/ID ratio of the Raman spectroscopic intensity of the carbon nanotube is 0.75 or more.

11. An electron microscope according to claim 10, wherein the carbon nanotube contains any of boron, nitrogen, phosphor, and sulfur atoms in a pyridine structure.

12. An electron microscope according to claim 10, wherein the carbon nanotube contains, in the structure, any of boron, nitrogen, phosphor, and sulfur atoms and a similar impurity atom is located nearest to the atom.

13. An electron microscope according to claim 10, wherein the carbon nanotube is used singly or in bundle and the diameter thereof is 50 to 200 nm.

14. An electron microscope according to claim 10, wherein the carbon nanotube is 2 to 10 μm in length and projects 0.5 to 3.0 μm from a conductive base.

15. An electron source comprising an electron emitting cathode equipped with a carbon nanotube and an extraction unit to field-emitting electrons, wherein
the carbon nanotube is formed approximately conical shape at the tip portion thereof closed at the electron-emitting cathode.

16. An electron source according to claim 15, wherein the carbon nanotube contains 0.1 to 5 mol % of at least one of boron, nitrogen, phosphor, and sulfur and the IG/ID ratio of the Raman spectroscopic intensity of the carbon nanotube is 0.75 or more.

17. An electron beam lithography system using the electron source according to claim 15.
